(19) United States
(12) Patent Application Publication
(10) Pub. No.: US 2014/0091351 A1
(43) Pub. Date: Apr. 3, 2014

(54) LIGHT EMITTING DIODE CHIP

(71) Applicant: LEXTAR ELECTRONICS CORPORATION, Hsinchu (TW)

(72) Inventor: Pei-Shiu Tsai, Taoyuan City (TW)

(73) Assignee: LEXTAR ELECTRONICS CORPORATION, Hsinchu (TW)

(21) Appl. No.: 13/761,948

(22) Filed: Feb. 7, 2013

(30) Foreign Application Priority Data
Oct. 3, 2012 (TW) 101136556

(51) Int. Cl. H01L 33/38

(52) U.S. Cl. CPC H01L 33/38
USPC 257/99

(57) ABSTRACT

A Light emitting diode (LED) chip includes a substrate, an N-type semiconductor layer, a luminous layer, a P-type semiconductor layer, an N-type electrode layer and a P-type electrode layer. The N-type semiconductor layer is mounted on the substrate. The luminous layer is mounted on the N-type semiconductor layer. The P-type semiconductor layer is mounted on the luminous layer. The N-type electrode layer is mounted on the N-type semiconductor layer. The P-type electrode layer is mounted on the P-type semiconductor layer, and includes a plurality of enclosed circuit patterns. These enclosed circuit patterns respectively encompass different parts of the N-type electrode layer.

### RELATED APPLICATIONS

This application claims priority to Taiwan Application Serial Number 101136556, filed Oct. 3, 2012, which is herein incorporated by reference.

### BACKGROUND

1. Technical Field

Embodiments of the present invention relate to an illumination apparatus. More particularly, embodiments of the present invention relate to a light emitting diode (LED) chip.

2. Description of Related Art

Light emitting diodes (LEDs) are eco-friendly, and as a result, have been quickly replacing conventional incandescent light bulbs and fluorescent lamps.

A typical LED chip includes an epitaxial stack structure. The epitaxial stack structure includes an N-type semiconductor layer, a luminous layer and a P-type semiconductor layer stacked sequentially. An N-type electrode is mounted on the N-type semiconductor layer, and a P-type electrode is mounted on the P-type semiconductor layer. When a voltage is applied to the N-type electrode and the P-type electrode, the electrons and electron holes can be combined in the multiple quantum well (MQW) to emit light.

The typical N-type electrode and P-type electrode are in circular conductive patterns, and they are formed at two opposite corners on the top surface of the LED chip for connecting wires. However, if the LED chip is large, the current in the area beyond the diagonal line of the LED chip will be lower than the current on the diagonal line of the LED chip, so that the current is not uniform, thereby causing problems such as heat concentration, illumination non-uniformity and so on. Further, the non-uniformity of the current also makes the forward voltage of the LED increase, so that a higher voltage is required to drive the LED, thereby lowering the energy conversion efficiency of the LED.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In accordance with one embodiment of the present invention, a light emitting diode (LED) chip includes a substrate, an N-type semiconductor layer, a luminous layer, a P-type semiconductor layer, an N-type electrode layer and a P-type electrode layer. The N-type semiconductor layer is mounted on the substrate. The luminous layer is mounted on the N-type semiconductor layer. The P-type semiconductor layer is mounted on the luminous layer. The N-type electrode layer is mounted on the N-type semiconductor layer. The P-type electrode layer is mounted on the P-type semiconductor layer. The P-type electrode layer includes a plurality of enclosed circuit patterns, and the enclosed circuit patterns respectively encompass different parts of the N-type electrode layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of an LED chip in accordance with the first embodiment of the present invention;

FIG. 2 is a cross-sectional view along line A-A′ in FIG. 1;

FIG. 3 is a top view of an LED chip in accordance with the second embodiment of the present invention;

FIG. 4 is a cross-sectional view along line B-B′ in FIG. 3;

FIG. 5 is a top view of an LED chip in accordance with the third embodiment of the present invention;

FIG. 6 is a cross-sectional view along line C-C′ in FIG. 5;

FIG. 7 is a top view of an LED chip in accordance with the fourth embodiment of the present invention;

FIG. 8 is a top view of an LED chip in accordance with the fifth embodiment of the present invention; and

FIG. 9 is a cross-sectional view along line D-D′ in FIG. 8.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

### Embodiment 1

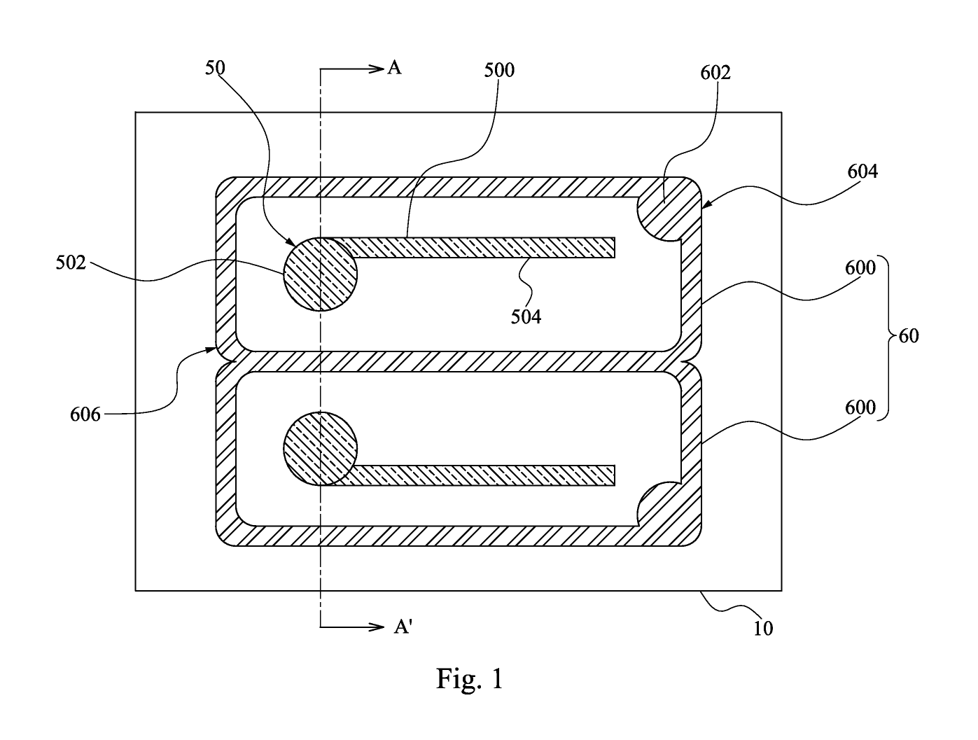

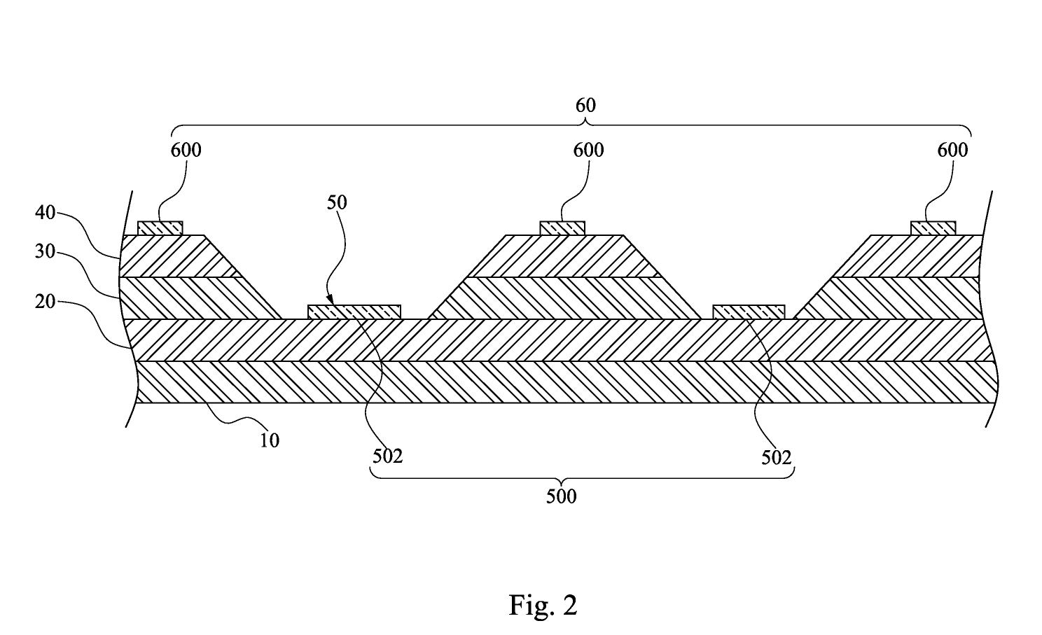

FIG. 1 is a top view of an LED chip in accordance with the first embodiment of the present invention. FIG. 2 is a cross-sectional view along line A-A′ in FIG. 1. As shown in FIGS. 1 and 2, the LED chip includes a substrate 10, an N-type semiconductor layer 20, a luminous layer 30, a P-type semiconductor layer 40, an N-type electrode layer 50 and a P-type electrode layer 60. The N-type semiconductor layer 20 is mounted on the substrate 10. The luminous layer 30 is mounted on the N-type semiconductor layer 20. The P-type semiconductor layer 40 is mounted on the luminous layer 30. The N-type electrode layer 50 is mounted on the N-type semiconductor layer 20. The P-type electrode layer 60 is mounted on the P-type semiconductor layer 40. The P-type electrode layer 60 includes a plurality of enclosed circuit patterns 600, and the enclosed circuit patterns 600 respectively encompass different parts of the N-type electrode layer 50, as will be described below.

In this embodiment, the enclosed circuit patterns 600 are adjoined in a column, and the N-type electrode layer 50 includes a plurality of N-type electrode patterns 500. The N-type electrode patterns 500 are respectively encompassed by the enclosed circuit patterns 600. Specifically, each of the enclosed circuit patterns 600 is formed as a rectangular loop, and each enclosed circuit pattern 600 encompasses one N-type electrode pattern 500.

Because the P-type electrode layer 60 and the N-type electrode layer 50 respectively include numerous enclosed circuit patterns 600 and numerous N-type electrode patterns 500, and each enclosed circuit pattern 600 encompasses one N-type electrode pattern 500, even if the LED chip is large, there is a small distance between each of the N-type electrode patterns 500 and the corresponding enclosed circuit pattern 600. As a result, the current is uniform on different areas of the LED chip, so that heat is not concentrated, the forward voltage is lowered, and the illumination is uniform.

In this embodiment, using one of the N-type electrode patterns 500 and the corresponding enclosed circuit pattern 600 as an example, the N-type electrode pattern 500 includes an N-type bonding area 502, and the enclosed circuit pattern 600 includes a P-type bonding area 602. The P-type bonding area 602 is positioned at a first corner 604 of the enclosed circuit pattern 600 farthest from the N-type bonding area 502. Specifically, the N-type bonding area 502 is positioned at one end of the N-type electrode pattern 500, and is closest to a second corner 606 of the enclosed circuit pattern 600. The second corner 606 is opposite to the first corner 604, that is, a line connecting the first corner 604 and the second corner 606 is one of the two diagonal lines of the rectangular enclosed circuit pattern 600. Therefore, in the area encompassed by the enclosed circuit pattern 600, the N-type bonding area 502 and the P-type bonding area 602 are substantially positioned on the opposite corners of the enclosed circuit pattern 600, so as to prevent the current from only distributing in certain areas in the enclosed circuit pattern 600. In other words, because the P-type bonding area 602 is positioned on the first corner 604 of the enclosed circuit pattern 600, and the N-type bonding area 502 is positioned near the second corner 606 of the enclosed circuit pattern 600, and further because the first corner 604 and the second corner 606 are opposite, the current can be uniformly distributed to all areas of the enclosed circuit pattern 600.

In this embodiment, the N-type bonding area 502 and the P-type bonding area 602 are used to electrically connect to external wires, such as gold lines (not shown). In this case, the end of external wires can be directly bonded on the N-type bonding area 502 and the P-type bonding area 602. In some embodiments, the N-type bonding area 502 and the P-type bonding area 602 can be circular or elliptic, but are not limited to any particular shape.

In this embodiment, the N-type electrode patterns 500 are formed as elongated strips and parallel to each other, and the N-type electrode patterns 500 are spatially separated and are encompassed by different enclosed circuit patterns 600. Specifically, each of the N-type electrode patterns 500 may include an elongated strip electrode pattern 504, and the elongated strip electrode pattern 504 extends from the N-type bonding area 502 and is parallel to the lengthwise edge of the enclosed circuit pattern 600. The elongated strip electrode patterns 504 of different N-type electrode patterns 500 are parallel to each other.

In this embodiment, the N-type electrode layer 50 and the P-type electrode layer 60 can be formed by metal or ITO, but are not limited to any particular material. In this embodiment, the N-type semiconductor layer 20 is a nitride semiconductor doped with an N-type impurity, such as N-GaN, which is formed by doping group 4A elements, such as Silicon, in pure GaN. In this embodiment, the P-type semiconductor layer 40 is a nitride semiconductor doped with a P-type impurity, such as P-GaN, which is formed by doping group 2A elements, such as Magnesium, in pure GaN. In this embodiment, the luminous layer 30 includes a plurality of quantum wells to facilitate combination therein of the electrons and electronic holes provided by the N-type semiconductor layer 20 and the P-type semiconductor layer 40.

### Embodiment 2

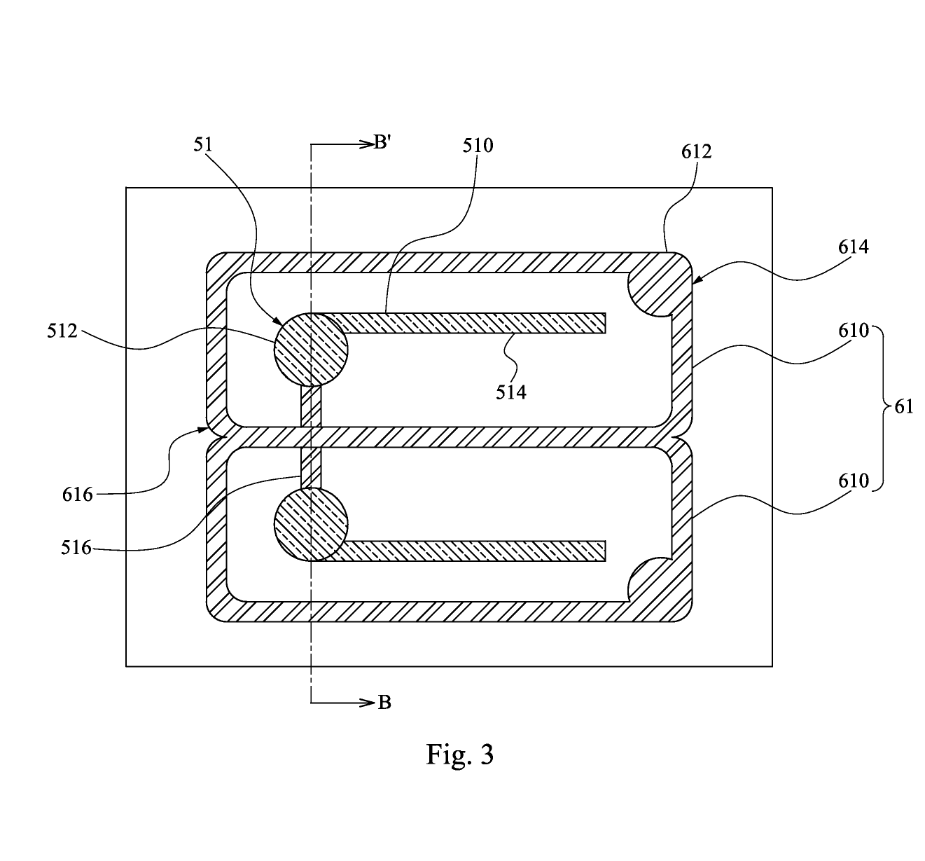

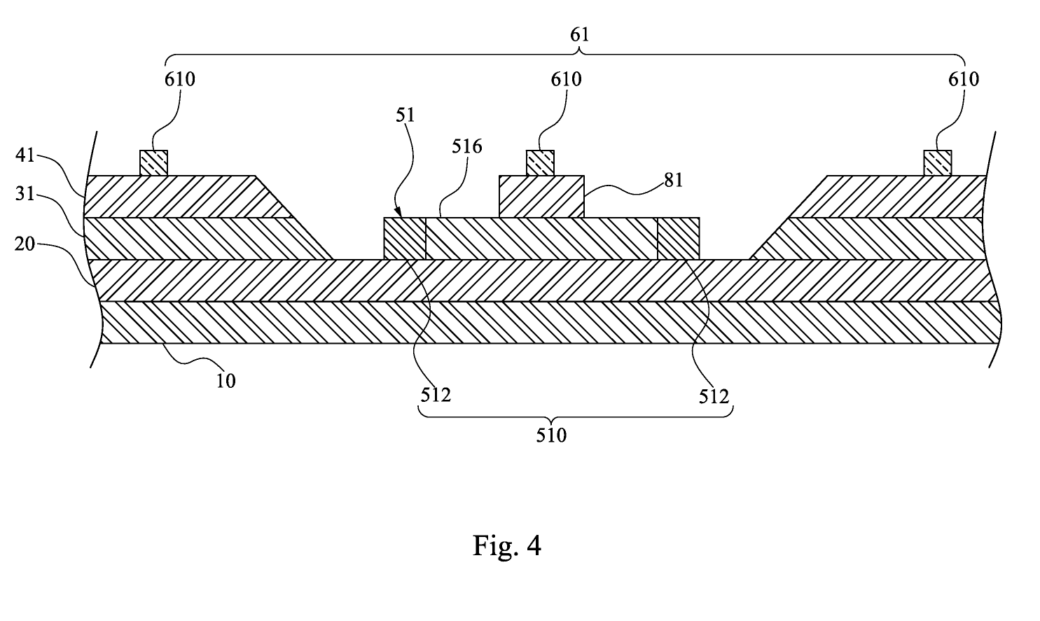

FIG. 3 is a top view of an LED chip in accordance with the second embodiment of the present invention. FIG. 4 is a cross-sectional view along line B-B′ in FIG. 3. As shown in FIGS. 3 and 4, the main difference between this embodiment and the embodiment in FIG. 1 is that the N-type electrode layer 51 includes an electrode connection pattern 516 connecting the N-type electrode patterns 510.

Specifically, each of the N-type electrode patterns 510 includes the N-type bonding area 512 at the end thereof, and the electrode connection pattern 516 is connected between two N-type bonding areas 512. Each N-type electrode pattern 510 includes an electrode pattern 514 which is formed as an elongated strip. The elongated strip electrode patterns 514 are parallel to each other. The N-type electrode patterns 510 and the electrode connection pattern 516 cooperate to form a U-shaped pattern. In other words, the lengthwise direction of the electrode connection pattern 516 is substantially perpendicular to the lengthwise direction of the elongated strip electrode patterns 514.

Because the P-type electrode layer 61 and the N-type electrode layer 51 respectively include numerous enclosed circuit patterns 610 and numerous N-type electrode patterns 510, and each enclosed circuit pattern 610 encompasses one N-type electrode pattern 510, even if the LED chip is large, there is a small distance between each of the N-type electrode patterns 510 and the corresponding enclosed circuit pattern 610. As a result, the current is uniform on different areas of the LED chip, so that heat is not concentrated, the forward voltage is lowered, and the illumination is uniform.

In this embodiment, using one of the N-type electrode patterns 510 and the corresponding enclosed circuit pattern 610 as an example, the P-type bonding area 612 is positioned at a first corner 614 of the enclosed circuit pattern 610 farthest from the N-type bonding area 512, and the enclosed circuit pattern 610 includes a second corner 616 closest to the N-type bonding area 512. Because the second corner 616 is opposite to the first corner 614, the N-type bonding area 512 and the P-type bonding area 612 are substantially positioned on the opposite corners of the enclosed circuit pattern 610, so that the current can be uniformly distributed to all areas of the enclosed circuit pattern 610.

In this embodiment, the enclosed circuit patterns 610 are positioned across the electrode connection pattern 516. In this embodiment, the LED chip includes an insulation layer 81 (See FIG. 4) mounted between the electrode connection pattern 516 and the enclosed circuit patterns 610, so as to prevent the electrode connection pattern 516 from contacting with the enclosed circuit patterns 610. In other words, the enclosed circuit patterns 610 are positioned above the insulation layer 81, and the electrode connection pattern 516 is positioned beneath the insulation layer 81, and therefore, the electrode connection pattern 516 and the enclosed circuit patterns 610 are separated by the insulation layer 81 and electrically insulated from each other.

In some embodiments, the height of the top surface of the insulation layer 81 is equal to the height of the top surface of the P-type semiconductor layer 41, so that the part of the enclosed circuit patterns 610 on the insulation layer 81 is at the same level with the other parts of the enclosed circuit patterns 610 on the P-type semiconductor layer 41. In some embodiments, the height of the top surface of the electrode connection pattern 516 is equal to the height of the top surface of the luminous layer 31, so that the insulation layer 81 is at the same level with the P-type semiconductor layer 41. In some embodiments, the material of the insulation layer 81 is a light transmissive oxide, such as, for example, SiO₂.

In this embodiment, the material of the electrode connection pattern 516 and the material of the N-type electrode patterns 510 may be the same. For example, the electrode connection pattern 516 and the N-type electrode patterns 510 can both be formed by metal or ITO, but are not limited to any particular material. In this embodiment, the N-type semiconductor layer 20 is a nitride semiconductor doped with an N-type impurity, such as N-GaN, which is formed by doping group 4A elements, such as Silicon, in pure GaN. In this embodiment, the P-type semiconductor layer 41 is a nitride semiconductor doped with a P-type impurity, such as P-GaN, which is formed by doping group 2A elements, such as Magnesium, in pure GaN. In this embodiment, the luminous layer 31 includes a plurality of quantum wells to facilitate combination therein of the electrons and electronic holes provided by the N-type semiconductor layer 20 and the P-type semiconductor layer 41.

### Embodiment 3

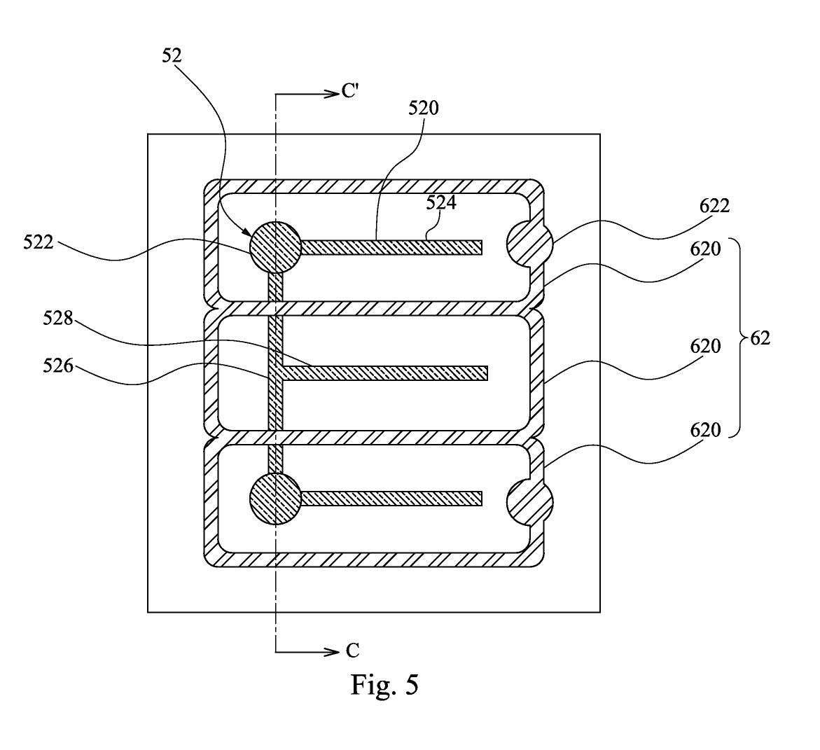

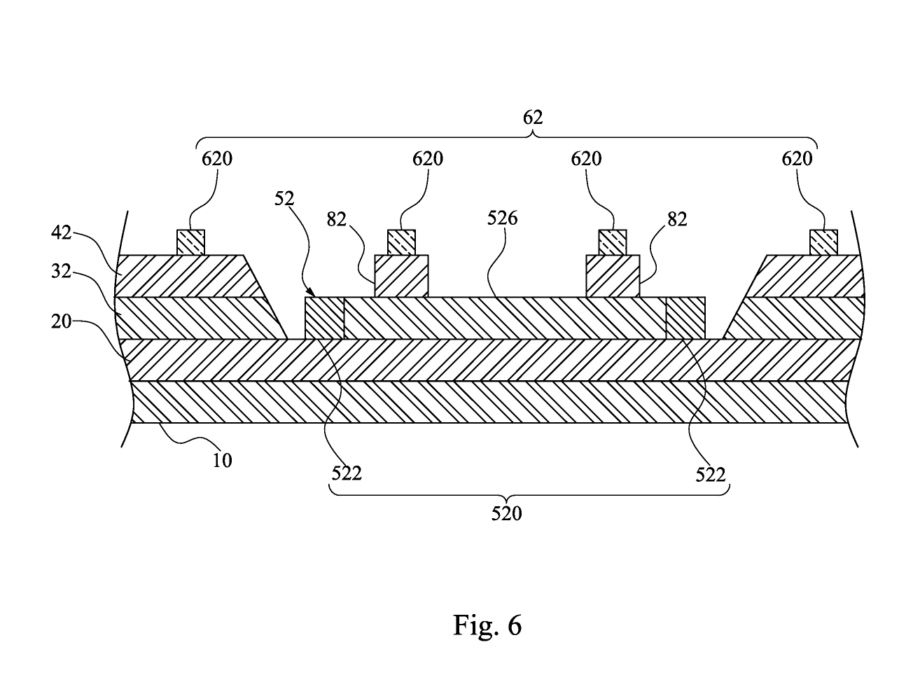

FIG. 5 is a top view of an LED chip in accordance with the third embodiment of the present invention. FIG. 6 is a cross-sectional view along line C-C′ in FIG. 5. As shown in FIGS. 5 and 6, the main difference between this embodiment and the second embodiment is that the number of the enclosed circuit patterns 620 is three, and the enclosed circuit patterns 620 are adjoined in a column. Further, the N-type bonding areas 522 are respectively positioned corresponding to the upper and the lower enclosed circuit patterns 620, and not corresponding to the middle enclosed circuit pattern 620. An N-type extending electrode 528 extends from the electrode connection pattern 526 at an area corresponding to the middle enclosed circuit pattern 620.

It is to be understood that while, in this embodiment, the number of the enclosed circuit patterns 620 is shown as three, in practice, the P-type electrode layer 62 can also include more than three enclosed circuit patterns 620, such as four, five, six, . . . or N enclosed circuit patterns 620, in which N is a natural number greater than three. Each enclosed circuit pattern 620 encompasses an N-type extending electrode 528 or an elongated strip electrode pattern 524. The number of the enclosed circuit patterns 620 can be changed as needed, depending on various factors, such as the size of the LED chip. By increasing the number of the enclosed circuit patterns 620, the current can be distributed more uniformly.

In this embodiment, the elongated strip electrode patterns 524 extend from the N-type bonding areas 522 toward the P-type bonding areas 622. Further, the N-type extending electrode 528 is substantially parallel to the elongated strip electrode patterns 524, and the elongated strip electrode patterns 524 and the N-type extending electrode 528 are all substantially perpendicular to the electrode connection pattern 526, so as to form a comb-shaped pattern.

In this embodiment, the insulation layer 82 (See FIG. 6) is mounted between the electrode connection pattern 526 and the enclosed circuit patterns 620, so as to prevent the electrode connection pattern 526 from contacting with the enclosed circuit patterns 620. In other words, the enclosed circuit patterns 620 across the electrode connection pattern 526 are positioned above the insulation layer 82, and the electrode connection pattern 526 is positioned beneath the insulation layer 82, and therefore, the electrode connection pattern 526 and the enclosed circuit patterns 620 are separated by the insulation layer 82 and electrically insulated from each other.

In some embodiments, the height of the top surface of the insulation layer 82 is equal to the height of the top surface of the P-type semiconductor layer 42, so that the parts of the enclosed circuit patterns 620 on the insulation layer 82 are at the same level with the other parts of the enclosed circuit patterns 620 on the P-type semiconductor layer 42. In some embodiments, the height of the top surface of the electrode connection pattern 526 is equal to the height of the top surface of the luminous layer 32, so that the insulation layer 82 is at the same level with the P-type semiconductor layer 42. In some embodiments, the material of the insulation layer 82 is a light transmissive oxide, such as, for example, SiO₂.

In this embodiment, the material of the electrode connection pattern 526, the material of the N-type extending electrode 528 and the material of the N-type electrode patterns 520 may be the same. For example, the electrode connection pattern 526, the N-type extending electrode 528 and the N-type electrode patterns 520 can all be formed by metal or ITO, but are not limited to any particular material. In this embodiment, the N-type semiconductor layer 20 is a nitride semiconductor doped with an N-type impurity, such as N-GaN, which is formed by doping group 4A elements, such as Silicon, in pure GaN. In this embodiment, the P-type semiconductor layer 42 is a nitride semiconductor doped with a P-type impurity, such as P-GaN, which is formed by doping group 2A elements, such as Magnesium, in pure GaN. In this embodiment, the luminous layer 32 includes a plurality of quantum wells to facilitate combination therein of the electrons and electronic holes provided by the N-type semiconductor layer 20 and the P-type semiconductor layer 42.

### Embodiment 4

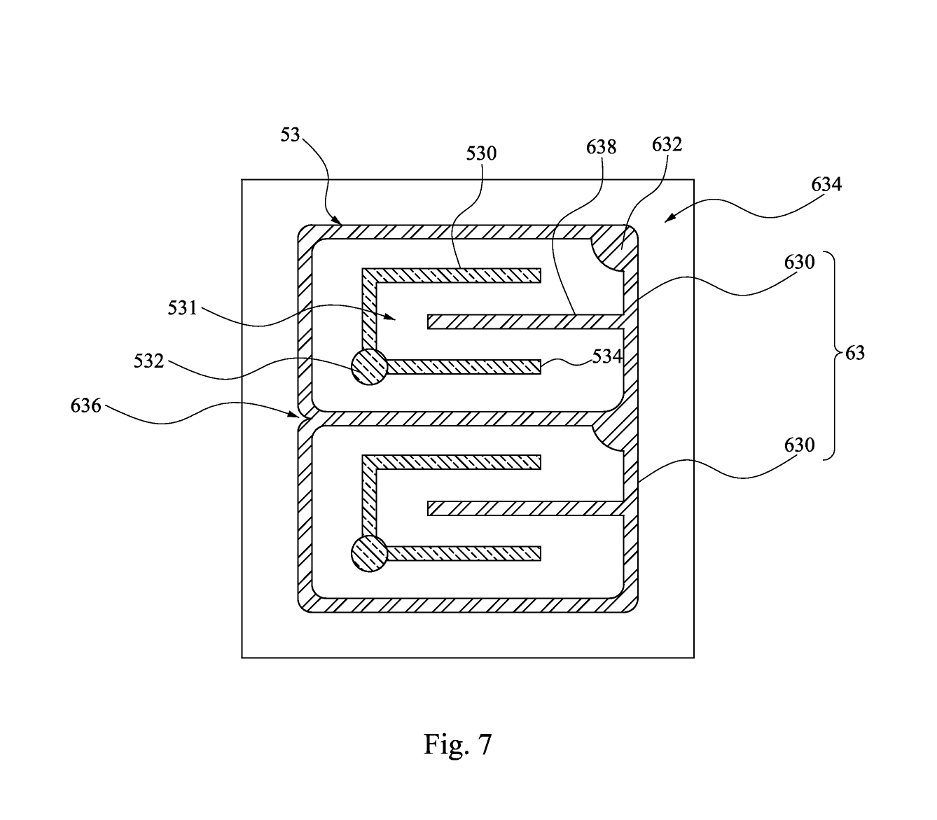

FIG. 7 is a top view of an LED chip in accordance with the fourth embodiment of the present invention. As shown in FIG. 7, the main difference between this embodiment and the foregoing embodiments is that the N-type electrode patterns 530 are U-shaped. Specifically, each of the N-type electrode patterns 530 of the N-type electrode layer 53 includes a U-shaped opening 531, and the corresponding enclosed circuit pattern 630 of the P-type electrode layer 63 includes a P-type extending electrode 638 perpendicularly extending from an edge of the enclosed circuit pattern 630 into the U-shaped opening 531 of the N-type electrode pattern 530.

Because the P-type extending electrode 638 extends into the U-shaped opening 531 of the N-type electrode pattern 530, the distance between the P-type extending electrode 638 and the N-type electrode pattern 530 is reduced, so that the current can be distributed more uniformly.

In some embodiments, the P-type extending electrode 638 perpendicularly extends from the edge of the enclosed circuit pattern 630 into the U-shaped opening 531. In other words, the P-type extending electrode 638 extends along the direction parallel to the lengthwise direction of the elongated strip electrode pattern 534.

In this embodiment, the P-type bonding area 632 of each of the enclosed circuit patterns 630 is positioned at a first corner 634 of the enclosed circuit pattern 630 farthest from the N-type bonding area 532 of the corresponding N-type electrode pattern 530. The N-type bonding area 532 is closest to a second corner 636 of the enclosed circuit pattern 630, and the second corner 636 is opposite to the first corner 634. Because the N-type bonding area 532 and the P-type bonding area 632 are substantially positioned on the opposite corners of the enclosed circuit pattern 630, the current can be uniformly distributed to all areas of the enclosed circuit pattern 630.

### Embodiment 5

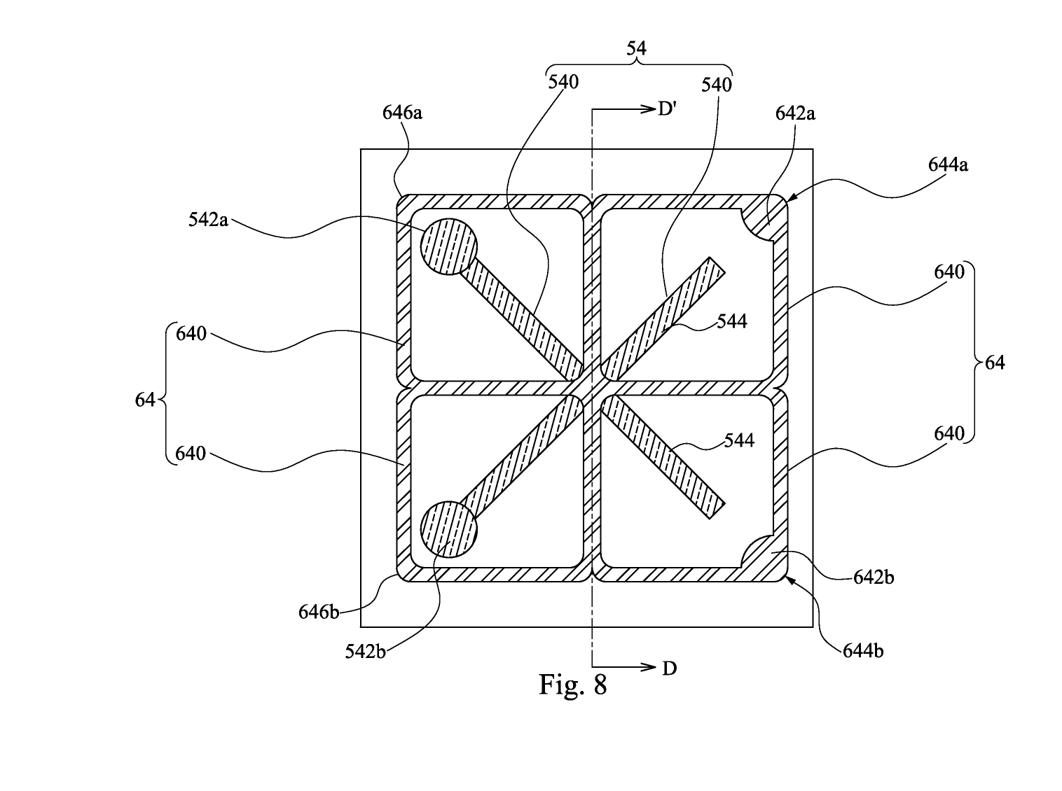

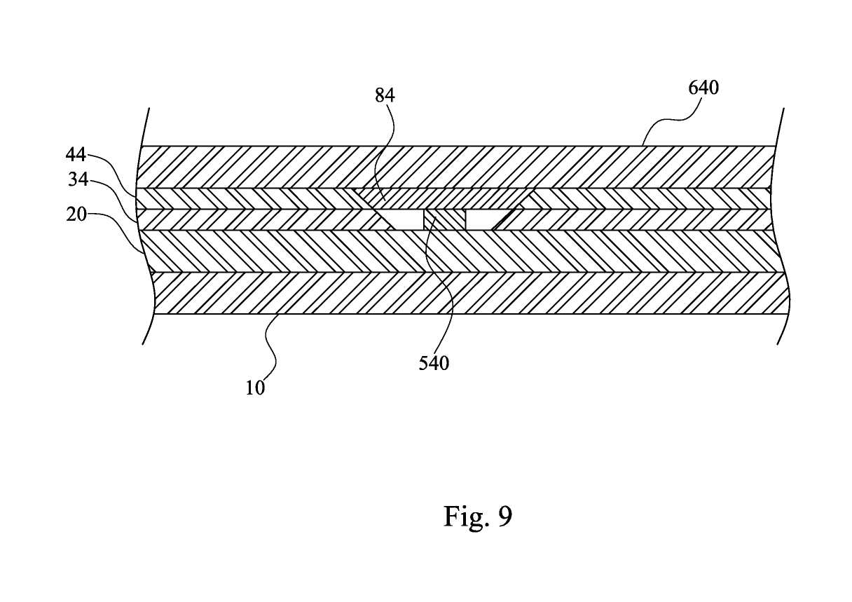

FIG. 8 is a top view of an LED chip in accordance with the fifth embodiment of the present invention. FIG. 9 is a cross-sectional view along line D-D′ in FIG. 8. As shown in FIGS. 8 and 9, the main difference between this embodiment and the foregoing embodiments is that the enclosed circuit patterns 640 are arranged in the form of a two-dimensional array, and are not arranged in a column. Specifically, two adjacent sides of any of the enclosed circuit patterns 640 are adjoined with two of the other enclosed circuit patterns 640, so that all of the enclosed circuit patterns 640 cooperate to form a 2×2 array.

In this embodiment, the N-type electrode patterns 540 of the N-type electrode layer 54 cross each other, and the intersection therebetween is positioned beneath the area where the four adjacent enclosed circuit patterns 640 meet, i.e., the joining area among the four adjacent circuit patterns 640. Specifically, the lengthwise directions of the elongated strip electrode patterns 544 of the N-type electrode patterns 540 are not parallel to each other, and these elongated strip electrode patterns 544 cross each other at the joining area among the enclosed circuit patterns 640. Therefore, each enclosed circuit pattern 640 encompasses part of one of the elongated strip electrode patterns 544, so that the current can be distributed more uniformly.

As shown in FIGS. 8 and 9, one N-type electrode pattern 540 extends from the upper left enclosed circuit pattern 640 to the lower right enclosed circuit pattern 640, and another N-type electrode pattern 540 extends from the lower left enclosed circuit pattern 640 to the upper right enclosed circuit pattern 640, so that the current can be distributed more uniformly.

In this embodiment, the upper left enclosed circuit pattern 640 encompasses the N-type bonding area 542a of one N-type electrode pattern 540. The N-type bonding area 542 is close to the second corner 646a of the enclosed circuit pattern 460. The lower right enclosed circuit pattern 640 includes the P-type bonding area 642b positioned at the first corner 644b of the lower right enclosed circuit pattern 640. The first corner 644b and the second corner 646a form opposite corners of the 2×2 array. In other words, the N-type bonding area 542a and the P-type bonding area 642b are substantially positioned at opposite corners of the 2×2 array, so as to increase the distance therebetween and to thereby distribute the current more uniformly. Similarly, the lower left enclosed circuit pattern 640 encompasses the N-type bonding area 542b of the other N-type electrode pattern 540. The N-type bonding area 542b is close to the second corner 646b of the lower left enclosed circuit pattern 640. The upper right enclosed circuit pattern 640 includes the P-type bonding area 642a positioned at the first corner 644a of the upper right enclosed circuit pattern 640. The first corner 644a and the second corner 646b are positioned at the other opposite corners of the 2×2 array, so as to increase the distance therebetween and to thereby distribute the current more uniformly.

In this embodiment, as shown in FIG. 9, the insulation layer 84 is mounted between the enclosed circuit patterns 640 and the intersection between the N-type electrode patterns 540, so as to prevent the N-type electrode pattern 540 from contacting with the enclosed circuit patterns 640. In other words, the enclosed circuit patterns 640 are positioned across the N-type electrode patterns 540 and above the insulation layer 84, and the N-type electrode patterns 540 are positioned beneath the insulation layer 84, and therefore, the N-type electrode patterns 540 and the enclosed circuit patterns 640 can be separated by the insulation layer 84 and electrically insulated from each other. In some embodiments, the material of the insulation layer 84 is a light transmissive oxide, such as, for example, SiO₂.

In some embodiments, the N-type electrode patterns 540 are perpendicular to each other. Specifically, the elongated strip electrode patterns 544 of the N-type electrode patterns 540 are perpendicular to each other. In other words, the angle between the N-type electrode patterns 540 is approximately 90 degrees.

In this embodiment, the N-type semiconductor layer 20 is a nitride semiconductor doped with an N-type impurity, such as N-GaN, which is formed by doping group 4A elements, such as Silicon, in pure GaN. In this embodiment, the P-type semiconductor layer 44 is a nitride semiconductor doped with a P-type impurity, such as P-GaN, which is formed by doping group 2A elements, such as Magnesium, in pure GaN. In this embodiment, the luminous layer 34 includes a plurality of quantum wells to facilitate combination therein of the electrons and electronic holes provided by the N-type semiconductor layer 20 and the P-type semiconductor layer 44.

It is noted that a description of “feature A being mounted on feature B” in this specification not only refers to an embodiment in which feature A directly contacts feature B, but also refers to an embodiment in which an additional feature C may be interposed between feature A and feature B. For example, with respect to the aforementioned characterization in which “the N-type semiconductor layer 20 is mounted on the substrate 10,” this not only refers to a configuration whereby the N-type semiconductor layer 20 directly contacts the substrate 10, but also refers to a configuration which may include an additional element, such as a heat dissipation layer, interposed between the N-type semiconductor layer 20 and the substrate 10.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode (LED) chip, comprising:
a substrate;
an N-type semiconductor layer mounted on the substrate;
a luminous layer mounted on the N-type semiconductor layer;
a P-type semiconductor layer mounted on the luminous layer;
an N-type electrode layer mounted on the N-type semiconductor layer; and
a P-type electrode layer mounted on the P-type semiconductor layer, wherein the P-type electrode layer comprises a plurality of enclosed circuit patterns, and the enclosed circuit patterns respectively encompass different parts of the N-type electrode layer.

2. The LED chip of claim 1, wherein the enclosed circuit patterns are adjoined in a column, and the N-type electrode layer comprises a plurality of N-type electrode patterns respectively encompassed by the enclosed circuit patterns.

3. The LED chip of claim 2, wherein each of some or all of the N-type electrode patterns comprises an N-type bonding area, and each of some or all of the enclosed circuit patterns comprises a P-type bonding area, and the P-type bonding area of any one of said each of some or all of the enclosed circuit patterns is positioned at a first corner of the enclosed circuit pattern farthest from the N-type bonding area of the N-type electrode pattern that the enclosed circuit pattern encloses.

4. The LED chip of claim 3, wherein the enclosed circuit pattern comprises a second corner closest to the N-type bonding area of the N-type electrode pattern that the enclosed circuit pattern encloses, and the second corner is opposite to the first corner.

5. The LED chip of claim 2, wherein the N-type electrode layer comprises an electrode connection pattern connecting the N-type electrode patterns.

6. The LED chip of claim 5, wherein the enclosed circuit patterns are positioned across the electrode connection pattern.

7. The LED chip of claim 6, further comprising an insulation layer mounted between the electrode connection pattern and the enclosed circuit patterns.

8. The LED chip of claim 7, wherein the material of the insulation layer is a light transmissive oxide.

9. The LED chip of claim 5, wherein the N-type electrode patterns and the electrode connection pattern cooperate to form a U-shaped pattern.

10. The LED chip of claim 5, wherein the N-type electrode patterns and the electrode connection pattern cooperate to form a comb-shaped pattern.

11. The LED chip of claim 2, wherein the N-type electrode patterns are formed as elongated strips and parallel to each other.

12. The LED chip of claim 2, wherein the N-type electrode patterns are U-shaped.

13. The LED chip of claim 12, wherein each of the enclosed circuit patterns comprises a P-type extending electrode perpendicularly extending from an edge of the enclosed circuit pattern into a U-shaped opening of the N-type electrode pattern that the enclosed circuit pattern encloses.

14. The LED chip of claim 2, wherein the enclosed circuit patterns are rectangular.

15. The LED chip of claim 1, wherein the enclosed circuit patterns are arranged in the form of a two-dimensional array.

16. The LED chip of claim 15, wherein two adjacent sides of any of the enclosed circuit patterns are adjoined with two of the other enclosed circuit patterns.

17. The LED chip of claim 15, wherein the N-type electrode layer comprises a plurality of N-type electrode patterns, and the N-type electrode patterns cross each other, and the intersection therebetween is positioned beneath a joining area among the four adjacent enclosed circuit patterns.

18. The LED chip of claim 17, wherein each of the N-type electrode patterns comprises an N-type bonding area encompassed by one of the enclosed circuit patterns, and the enclosed circuit pattern that is diagonal to said one of the enclosed circuit patterns comprises a P-type bonding area, the P-type bonding area being positioned at a first corner of the enclosed circuit pattern farthest from the N-type bonding area.

19. The LED chip of claim 17, further comprising an insulation layer mounted between the enclosed circuit patterns and the intersection between the N-type electrode patterns.

20. The LED chip of claim 19, wherein the material of the insulation layer is a light transmissive oxide.

21. The LED chip of claim 17, wherein the N-type electrode patterns are formed as elongated strips.

22. The LED chip of claim 21, wherein the N-type electrode patterns are perpendicular to each other.
